(19) United States
(12) Patent Application Publication
(10) Pub. No.: US 2007/0252146 A1
(43) Pub. Date: Nov. 1, 2007

(54) LIQUID CRYSTAL DISPLAY AND DEFECT REPAIRING METHOD FOR SAME

(75) Inventor: Masayuki Yokomizo, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: MITSUBISHI ELECTRIC CORPORATION, Chiyoda-ku (JP)

(21) Appl. No.: 11/742,102

(22) Filed: Apr. 30, 2007

(30) Foreign Application Priority Data
May 1, 2006 (JP) JP2006-127234

(51) Int. Cl. H01L 29/04

(52) U.S. Cl. 257/59

(57) ABSTRACT

The present invention provides a liquid crystal display having a plurality of gate lines, a plurality of source lines, a plurality of pixel electrodes provided in a matrix form, first TFTs having a first gate electrode connected to a gate line, a first source electrode connected to a source line and a first drain electrode connected to a pixel electrode for each pixel electrode, and second TFTs having a second gate electrode, a second source electrode and a second drain electrode for each pixel electrode. Second TFT does not have a portion which overlaps with at least one of gate line and pixel electrode in a plane, and second gate electrode and gate line and/or second drain electrode and pixel electrode are not electrically connected.

### BACKGROUND OF THE INVENTION

1. Field of the Invention

The present invention relates to a liquid crystal display and a defect repairing method for the same, and in particular, to a liquid crystal display having active elements and a defect repairing method for the same.

2. Description of the Background Art

Liquid crystal displays having TFTs (thin film transistors), which are active elements, are generally provided with pixels in a matrix form. In addition, each pixel is provided with a pixel electrode and a TFT for controlling the voltage for write-in into this pixel electrode. Here, control signals for TFTs are supplied through gate lines and the voltage for write-in into pixel electrodes is supplied through source lines.

It is difficult in liquid crystal displays where a great number of TFTs fabricated through a complicated manufacturing process are build in, to manufacture all of the TFTs without any defects. Therefore, it is necessary to repair defective TFTs, so that the yield in the manufacture of liquid crystal displays can be increased. As a method for this, there is a method for providing a redundant TFT structure in the liquid crystal display.

Specifically, a structure where a normally driven TFT and a spare TFT are provided to each pixel at the intersection between a gate line and a source line on an array substrate is described in Japanese Patent Application Laid-Open No. 04-149411 (1992-149411). In the case where a normally driven TFT is defective in such a liquid crystal display, optical energy, for example a laser, is applied in a portion where a drain electrode and a pixel electrode overlap in the spare TFT, so that the drain electrode and the pixel electrode are electrically connected and the pixel can be driven by the spare TFT. That is to say, in Japanese Patent Application Laid-Open No. 04-149411 (1992-149411), defective TFTs are switched to spare TFTs, thereby defective dots are repaired.

In the conventional redundant TFT structure shown in Japanese Patent Application Laid-Open No. 04-149411 (1992-149411), however, there is a difference between normal pixels and pixels that have been repaired (hereinafter referred to as repaired pixels), in terms of parasitic capacitance Cgd between the pixel electrode and the gate electrode. Therefore, there is a difference in the held voltage between normal pixels and repaired pixels when the same voltage is applied, and there is a difference in brightness between normal pixels and repaired pixels. That is to say, there is a difference in visibility between normal pixels and repaired pixels, and therefore, defective pixels cannot be repaired to have a display quality equal to that of normal pixels.

Furthermore, in the conventional redundant TFT structure, two TFTs are connected to one pixel, and therefore, parasitic capacitance Cgd becomes approximately two times greater, lowering the voltage held for the liquid crystal. As a result, the display quality lowers, due to display irregularity and the like. In addition, the line load capacitance of the gate lines and the source lines also increases to approximately two times greater, and therefore, in the case where the conventional redundant TFT structure is applied to a liquid crystal display with high resolution, display irregularity may be caused due to delay of a drive signal and the like.

### SUMMARY OF THE INVENTION

An object of the present invention is to provide a liquid crystal display having high display quality where defective dots caused by TFTs can be repaired to normal pixels, and a defect repairing method for the same.

The liquid crystal display according to the present invention includes a plurality of gate lines, a plurality of source lines provided so as to be perpendicular to the gate lines, a plurality of pixel electrodes provided in a matrix form so as to correspond to intersections of the gate lines and the source lines, a first TFT having a first gate electrode connected to one of the gate lines, a first source electrode connected to one of the source lines, and a first drain electrode connected to one of the pixel electrodes, provided for each of the pixel electrodes, and a second TFT having a second gate electrode, a second source electrode and a second drain electrode, provided for each of the pixel electrode. Furthermore, in the liquid crystal display according to the present invention, the second TFT either does not have a portion which overlaps with any of the gate lines in a plane, and/or does not have a portion which overlaps with any of the pixel electrodes in a plane. The second gate electrodes and the gate lines and/or the second drain electrodes and the pixel electrodes are not electrically connected.

In the liquid crystal display according to the present invention, since second TFT does not have any portion which overlaps with at least one of the gate line and the pixel electrode in a plane, and the second gate electrode and the gate line or the second drain electrode and the pixel electrode are not electrically connected, defective dots caused by TFTs can be repaired to normal pixels, and a liquid crystal display having high display quality can be provided.

The defect repairing method according to the present invention is a method for repairing a defect in a liquid crystal display, which includes a plurality of gate lines, a plurality of source lines, a plurality of pixel electrodes, a first TFT, and a second TFT, wherein the second TFT either does not have a portion which overlaps with any of the gate lines in a plane, and/or does not have a portion which overlaps with any of the pixel electrodes in a plane, and the second gate electrodes and the gate lines and/or the second drain electrodes and the pixel electrodes are not electrically connected. In addition, the defect repairing method according to the present invention includes the steps of cutting out a first drain electrode of a first TFT having a defect from a pixel electrode, and making a connection in an electrically unconnected portion from among the portion between the second gate electrode of the second TFT corresponding to those in the first TFT having a defect and the gate line, the portion between the second source electrode and the source line, and the portion between the second drain electrode and the pixel electrode, in accordance with a predetermined film forming technique.

Since the defect repairing method according to the present invention includes the steps of cutting out a first drain electrode of a first TFT from a pixel electrode, and connecting a portion in a second TFT which is not electrically connected in accordance with a predetermined film forming technique, defective dots caused by TFTs can be repaired to normal pixels, and a liquid crystal display having high display quality can be provided.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view showing a configuration of one pixel of a liquid crystal display according to a first embodiment of the present invention;

FIG. 2 is a plan view showing a configuration of one pixel of a liquid crystal display according to the first embodiment of the present invention after a repairing process;

FIG. 3 is a graph showing a drive waveform for a liquid crystal display according to the first embodiment of the present invention;

FIG. 4 is a circuit diagram showing a circuit equivalent to one pixel of a liquid crystal display according to the first embodiment of the present invention;

FIG. 5 is a circuit diagram showing a circuit equivalent to one pixel of a liquid crystal display according to the first embodiment of the present invention after a repairing process;

FIG. 6 is a plan view showing a configuration of one pixel of a liquid crystal display according to a second embodiment of the present invention;

FIG. 7 is a plan view showing a configuration of one pixel of a liquid crystal display according to a third embodiment of the present invention;

FIG. 8 is a plan view showing a configuration of one pixel of a liquid crystal display according to a fourth embodiment of the present invention; and

FIG. 9 is a plan view showing a configuration of one pixel of a liquid crystal display according to a fifth embodiment of the present invention.

### DESCRIPTION OF THE PREFERRED EMBODIMENTS

### First Embodiment

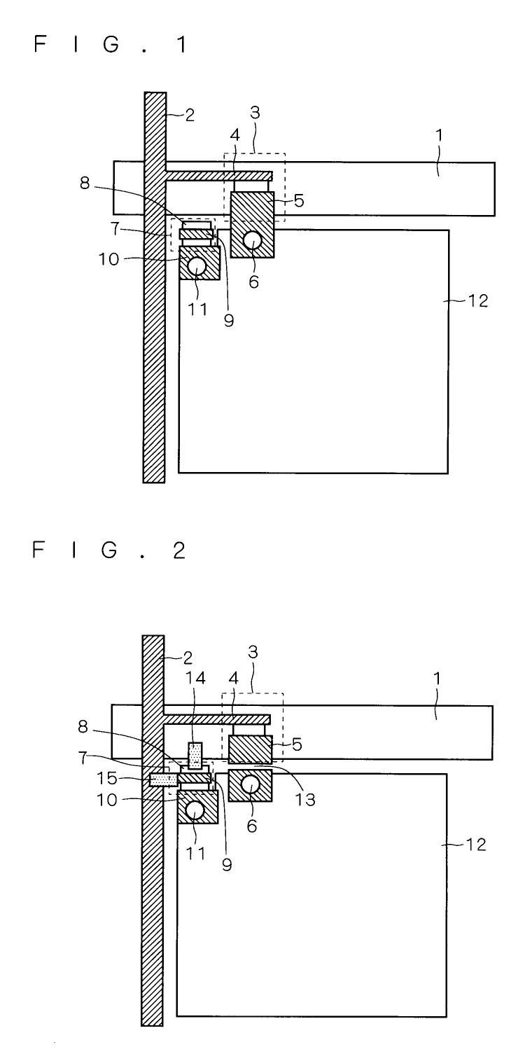

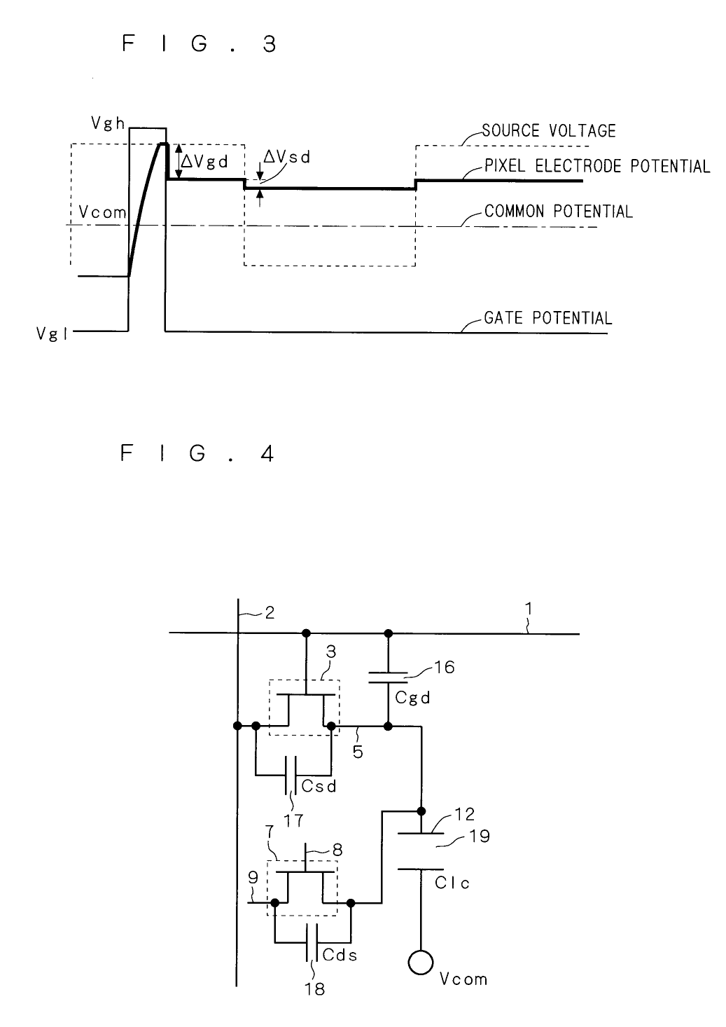

A liquid crystal display according to the present embodiment is described with reference to FIGS. 1 and 2. FIG. 1 is a plan view showing a configuration of one pixel before a defect is repaired in a liquid crystal display having a redundant TFT structure. In addition, FIG. 2 is a plan view showing a configuration of one pixel after the defect has been repaired in the liquid crystal display of FIG. 1. First, in FIG. 1, a gate line 1 and a source line 2 are provided to intersect with each other, and a TFT 3 which is used for normal drive is provided in the vicinity of the intersection. This TFT 3 is provided with a source electrode 4 for connection to source line 2, and a drain electrode 5 for connection to a pixel electrode 12 through a contact hole 6. Gate line 1 is used as the gate electrode of TFT 3.

Furthermore, the liquid crystal display according to the present embodiment has a redundant TFT structure, and therefore, is provided with a spare TFT, in addition to the TFT used for normal drive. In FIG. 1, a spare TFT 7 is provided between source line 2 and TFT 3. This TFT 7 is provided with a gate electrode 8 which is not connected to gate line 1, a source electrode 9, which is not connected to source line 2, and a drain electrode 10, which is connected to pixel electrode 12 via a contact hole 11.

In addition, spare TFT 7 according to the present embodiment does not have a portion which overlaps with gate line 1 in a plane, as shown in FIG. 1, and has gate electrode 8, which is not electrically connected to gate line 1. Here, since the structure of TFT 3 and TFT 7 is approximately the same as the structure of conventional TFTs, detailed description thereof is omitted.

It is possible to form the pattern shown in FIG. 1 by repeating film formation and photoengraving several times on a glass substrate. Specifically, gate line 1, source line 2, drain electrodes 5 and 10, and pixel electrode 12, which are shown in FIG. 1, and in addition, a gate insulating film, a semiconductor layer, for example of amorphous Si, and a protective film, which are not shown, are formed on the glass substrate. The glass substrate shown in FIG. 1 forms an array substrate of the liquid crystal display according to the present embodiment. Here, in addition to the array substrate, the liquid crystal display has a facing substrate where a color filter or the like is formed on a glass substrate, which is not an essential part of the present invention, and thus, detailed description is omitted.

Next, an array inspecting apparatus provided during the manufacturing process detects defects in the TFTs caused by a defective pattern or the like by electrically or optically inspecting the completed array substrate. In the case where there is a defect, the array substrate is conveyed to a laser repairing apparatus. This laser repairing apparatus can immediately move to the location of the defect based on the information on the location of the defect, which is sent from the above described array inspecting apparatus to a host server, and thus, the detected defect in a TFT can be confirmed by the eye.

In the case where the TFT defect is determined to be repairable after the confirmation by the eye, the laser repairing apparatus carries out the following defect repairing process (repairing process). First, TFT 3 which is used for normal drive and is determined to be a defective TFT is separated. Specifically, the portion between drain electrode 5 of TFT 3 and contact hole 6 is cut by a laser or the like. In FIG. 2, a cut portion 13 is created between drain electrode 5 of TFT 3 and contact hole 6. As a result, the electrical connection between drain electrode 5 and pixel electrode 12 is cut.

After that, gate line 1 and gate electrode 8 of TFT 7 are connected through a partial film forming method, such as laser CVD (chemical vapor deposition). In FIG. 2, gate line 1 and gate electrode 8 are connected through a partially formed film portion 14. In the same manner, source line 2 and source electrode 9 of TFT 7 are connected through a partial film forming method, such as laser CVD. A predetermined voltage can be applied to pixel electrode 12 by providing partially formed film portions 14 and 15, and thus, TFT 7 can drive the pixel in the same manner as other pixels driven by TFTs 3.

After the above described repairing process, the array substrate is made to overlap with a facing substrate, where color filters, facing electrodes and the like are formed, so that a liquid crystal panel is formed. Liquid crystal is injected into this liquid crystal panel, to which a polarizing plate, a drive IC and a backlight are then attached, and thus, a liquid crystal display is assembled and completed.

Next, electrical properties are compared between the pixel on which the above described repairing process (defective dot repairing) has been carried out and a normal pixel. First, FIG. 3 shows a drive waveform of one pixel. FIG. 3 illustrates a gate signal where the low level is Vgl and the high level is Vgh, and a source signal which fluctuates within a predetermined range in response to the common potential Vcom. In addition, in the case of an ideal TFT having the drive waveform of FIG. 3, at the point in time when the gate signal is turned on (when the level changes from Vgl to Vgh), the voltage of the source signal charges the pixel electrode, and when the gate signal is turned off (when the level changes from Vgh to Vgl), the voltage of the source signal at that point in time is held in the pixel electrode.

In conventionally manufactured TFTs, however, the potential held in the pixel electrode lowers, due to the effects of parasitic capacitance Cgd between the gate electrode and the drain electrode, and parasitic capacitance Csd between the source electrode and the drain electrode. FIG. 3 shows the potential of the pixel electrode of conventionally manufactured TFTs by a thick line. It can be seen that the amount of reduction in the held voltage (ΔVgd) caused by parasitic capacitance Cgd when the gate signal is turned off is particularly great in the pixel electrode potential shown in FIG. 3. Here, the amount of reduction in the held voltage caused by parasitic capacitance Csd is ΔVsd, as shown in FIG. 3.

The amount of reduction in the held voltage ΔVgd is proportional to Cgd/(Clc+Cgd). Here, Clc indicates the liquid crystal capacitance. Accordingly, in the case where Clc is 0.3 pF and Cgd is approximately 0.02 pF, the amount of reduction in the held voltage ΔVgd becomes approximately 1.8 times greater when two TFTs are used by adding a spare TFT, in comparison with a case where one normally driven TFT is used. The amount of reduction in the held voltage ΔVgd becoming greater means reduction in the voltage applied to the liquid crystal, and therefore, the brightness lowers in the case of normally black liquid crystal displays.

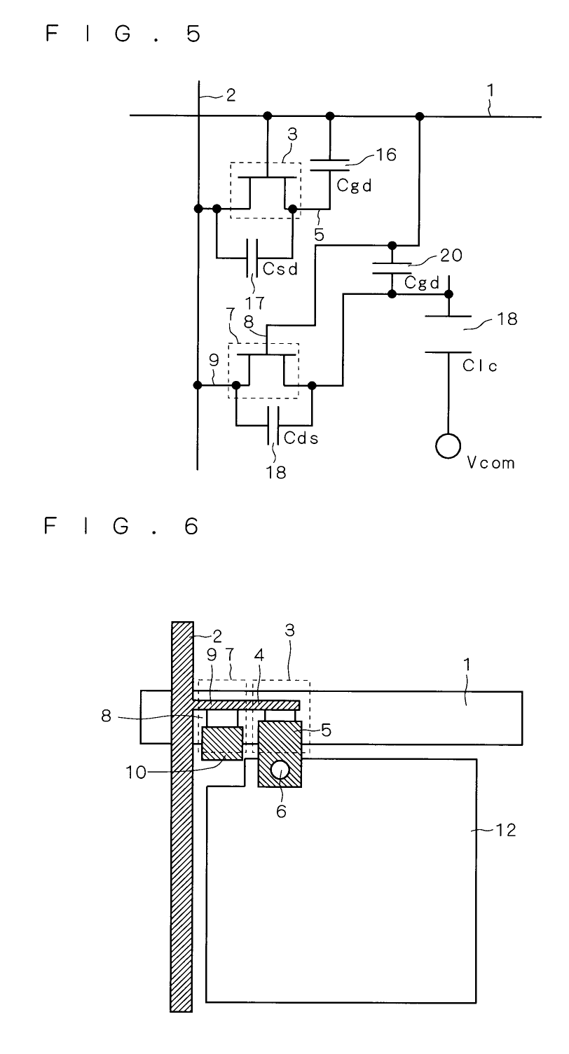

Therefore, an array substrate having the pattern shown in FIG. 1 is adopted in the liquid crystal display according to the present embodiment. Accordingly, TFT 7 does not have a portion which overlaps with gate line 1 in a plane, and therefore, gate electrode 8 is not connected to gate line 1, and thus, does not have any parasitic capacitance Cgd. FIG. 4 shows a circuit equivalent to one pixel of the liquid crystal display according to the present embodiment. In addition, FIG. 5 shows a circuit equivalent to one pixel of the liquid crystal display according to the present embodiment after a repairing process.

The amount of parasitic capacitance is proportional to the area of the electrode plate (area of electrodes which overlap in a plane). Accordingly, in the liquid crystal display according to the present embodiment, spare TFT 7 overlaps with neither gate line 1 nor source line 2, as shown in FIG. 1, and therefore, the parasitic capacitance between gate line 1 or source line 2 and each line of TFT 7 becomes very small in comparison with liquid crystal capacitance Clc, and is negligible. Therefore, in terms of the parasitic capacitance of TFT 7, the equivalent circuit of FIG. 4 shows only parasitic capacitance Cds 18 between the source electrode and the drain electrode, and does not show the other parasitic capacitances.

Accordingly, as shown in FIG. 4, the liquid crystal display according to the present first embodiment has only a parasitic capacitance Cgd 16 with TFT 3, in terms of parasitic capacitance Cgd with the liquid crystal capacitance Clc 19 of the pixel. Therefore, although the present embodiment provides a redundant TFT structure having TFTs 3 and TFTs 7, the amount of reduction in the held voltage ΔVgd is small, and a liquid crystal display having high display quality can be provided.

FIG. 5 shows an equivalent circuit after a repairing process, where drain electrode 3 of TFT 3 is separated from pixel electrode 12, and gate electrode 8 of TFT 7 and source electrode 9 of TFT 7 are connected to gate line 1 and source line 2, respectively. Therefore, parasitic capacitance Cgd 16 and parasitic capacitance Csd 17 of TFT 3 are separated from pixel electrode 12 after the repairing process, and therefore, the parasitic capacitance is negligible when the pixel is driven.

Meanwhile, spare TFT 7 is respectively connected to gate line 1 and source line 2, and thus, parasitic capacitance Cgd 20 and parasitic capacitance Cds 18 are connected to pixel electrode 12. Therefore, after the repairing process, parasitic capacitance Cgd 20 and parasitic capacitance Cds 18 with TFT 7 are added. Here, these parasitic capacitance Cgd 20 and parasitic capacitance Cds 18 are approximately equal to parasitic capacitance Cgd 16 and parasitic capacitance Csd 17 with TFT 3.

Accordingly, in the liquid crystal display according to the present embodiment, there is almost no change in the parasitic capacitance between pixel electrode 12 and gate line 1 or source line 2 before and after the repairing process. Therefore, it becomes possible for the pixel on which the repair process has been carried out to have display properties equal to those of normal pixels, even when it is driven under the same drive conditions as those for normal pixels.

Here, a configuration where source electrode 8 of TFT 7 shown in FIG. 1 is connected to source line 2 is possible as a modification of the liquid crystal display according to the present embodiment (not shown). In the configuration of the present modification, TFT 7 does not have a portion which overlaps with gate line 1 in a plane, and gate electrode 8 and gate line 1 are not electrically connected, and therefore, the same effects as in the present embodiment can be obtained. Here, in the present modification, source electrode 8 is connected to source line 2, and therefore, parasitic capacitance Cds with TFT 7 is added to pixel electrode 12. Therefore, when a repaired pixel and normal pixels in the present modification are compared, it can be found that the held voltage lowers by the added parasitic capacitance Cds.

### Second Embodiment

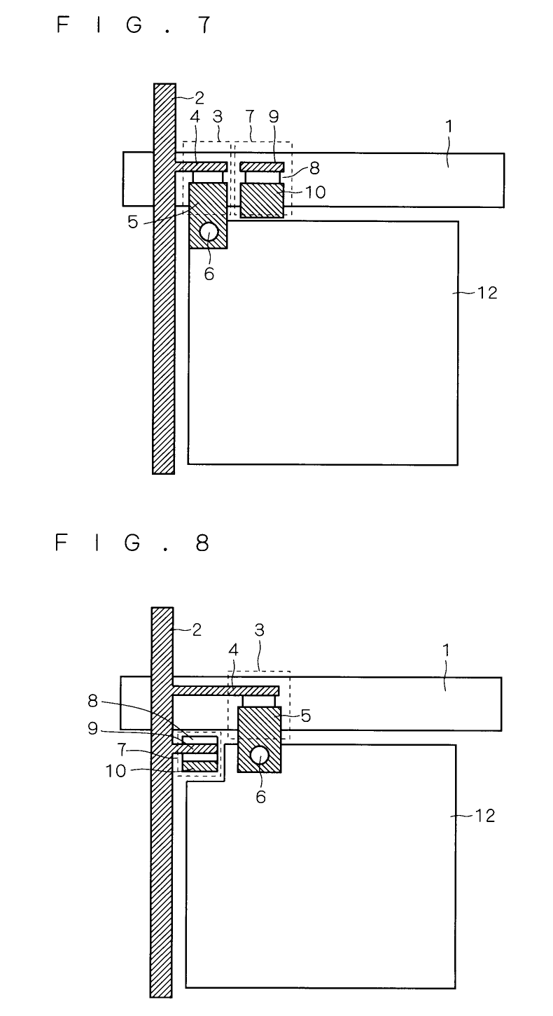

FIG. 6 is a plan view showing one pixel of the liquid crystal display according to the present embodiment before a defect is repaired. In FIG. 6, the configuration of TFT 3 is the same as the configuration of TFT 3 shown in FIG. 1, while the configuration of TFT 7 is different from the configuration of TFT 7 shown in FIG. 1. Specifically, TFT 7 shown in FIG. 6 is different from TFT 7 shown in FIG. 1 in that source electrode 9 is connected to source electrode 2, and gate line 1 is used as gate electrode 8. In addition, TFT 7 shown in FIG. 6 does not have an overlapping portion between drain electrode 10 and pixel electrode 12, and drain electrode 10 is separated from pixel electrode 12.

Therefore, parasitic capacitance Cgd with TFT 7 shown in FIG. 6 does not affect the potential of the pixel electrode at the time of normal drive. Accordingly, though the liquid crystal display according to the present embodiment shown in FIG. 6 has a redundant TFT structure having TFTs 3 and TFTs 7, as in the first embodiment, the amount of reduction in the held voltage ΔVgd is small, and a liquid crystal display having high display quality can be obtained. Here, in FIG. 6, the same configuration as that shown in FIG. 1 is provided, except that the configuration of TFT 7 is different, and therefore, detailed description is omitted.

Next, in the case where the liquid crystal display according to the present embodiment has a defect in a normally driven TFT 3, first, the portion between drain electrode 5 of TFT 3 and contact hole 6 is cut using a laser. This cutting is the same as that shown in FIG. 2 according to the first embodiment. Next, a partially formed film portion (not shown) is formed between drain electrode 10 of TFT 7 shown in FIG. 6 and pixel electrode 12 using a laser CVD, so that an electrical connection is made. As a result of the above described process, normally driven TFT 3 is switched to spare TFT 7, so that the pixel can be driven in the liquid crystal display according to the present embodiment.

Here also, there is almost no change in the parasitic capacitance between pixel electrode 12 and gate line 1 or source line 2 in the liquid crystal display according to the present embodiment before and after the repairing process. Therefore, it becomes possible for the pixel on which a repairing process has been carried out to gain display properties equal to those of normal pixels when driven under the same drive conditions as normal pixels.

### Third Embodiment

FIG. 7 is a plan view showing one pixel of the liquid crystal display according to the present embodiment before a defect is repaired. In FIG. 7, the configuration of TFT 3 is the same as the configuration of TFT 3 shown in FIG. 1, while the configuration of TFT 7 is different from the configuration of TFT 7 shown in FIG. 1. Specifically, TFT 7 shown in FIG. 7 is different from TFT 7 shown in FIG. 1 in that gate line 1 is used as gate electrode 8 and no overlapping portion is provided between drain electrode 10 and pixel electrode 12, and thus, drain electrode 10 is separated from pixel electrode 12. Here, TFT 7 shown in FIG. 7 is different from TFT 7 shown in FIG. 6 in that source electrode 9 is cut out from source line 2.

As described above, in the liquid crystal display according to the present embodiment, drain electrode 10 of TFT 7 is separated from pixel electrode 12, and therefore, parasitic capacitance Cgd with TFT 7 does not affect the potential of the pixel electrode at the time of normal drive. Accordingly, although the liquid crystal display according to the present embodiment shown in FIG. 7 has a redundant TFT structure having TFTs 3 and TFTs 7, as in the first embodiment, the amount of reduction in the held voltage ΔVgd is small, and a liquid crystal display having high display quality can be obtained. Here, in FIG. 7, the same configuration as that shown in FIG. 1 is provided, except that the configuration of TFT 7 is different, and therefore, detailed description is omitted.

In addition, the liquid crystal display according to the present embodiment is different from that according to the second embodiment in that spare TFT 7 is cut out from source line 2, and therefore, the load capacitance of source line 2 is reduced at the time of normal drive. Therefore, the liquid crystal display according to the present embodiment makes high speed operation possible, as in liquid crystal displays where no spare TFT 7 is formed, and thus, a liquid crystal display having high resolution and no defects can be manufactured with a high yield.

Next, in the case where there is a defect in normally driven TFT 3 in the liquid crystal display according to the present embodiment, first, the portion between drain electrode 5 of TFT 3 and contact hole 6 is cut using a laser. This cutting is the same as that shown in FIG. 2 according to the first embodiment. Next, a partially formed film portion (not shown) is formed between drain electrode 10 of TFT 7 shown in FIG. 7 and pixel electrode 12, as well as between source electrode 9 and source electrode 4 of TFT 3, which is connected to source line 2, through laser CVD, so that respective electrical connections are made. As a result of the above described process, in the liquid crystal display according to the present embodiment, normally driven TFT 3 can be switched to spare TFT 7, so that the pixel can be driven.

Here also, there is almost no change in the parasitic capacitance between pixel electrode 12 and gate line 1 or source line 2 in the liquid crystal display according to the present embodiment before and after the repairing process. Therefore, it becomes possible for the pixel on which a repairing process has been carried out to gain display properties equal to those of normal pixels when driven under the same drive conditions as normal pixels.

### Fourth Embodiment

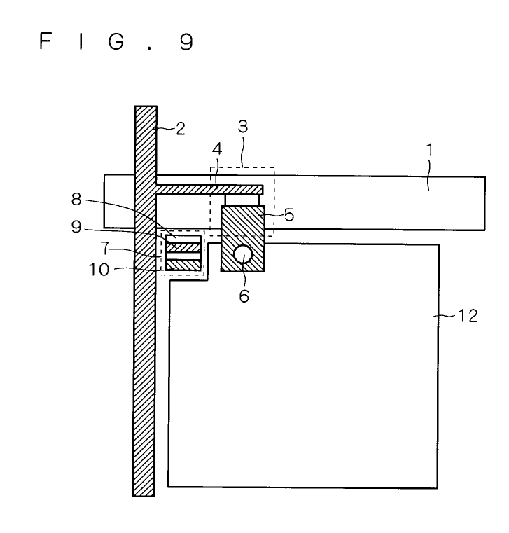

FIG. 8 is a plan view showing one pixel of the liquid crystal display according to the present embodiment before a defect is repaired. In FIG. 8, the configuration of TFT 3 is the same as the configuration of TFT 3 shown in FIG. 1, while the configuration of TFT 7 is different from the configuration of TFT 7 shown in FIG. 1. Specifically, TFT 7 shown in FIG. 8 is different from TFT 7 shown in FIG. 1 in that source electrode 9 is connected to source line 2, and no overlapping portion is provided between drain electrode 10 and pixel electrode 12, and thus, drain electrode 10 is separated from pixel electrode 12. Here, TFT 7 shown in FIG. 8 is different from TFT 7 shown in FIG. 6 in that no overlapping portion is provided between gate electrode 8 and gate line 1, and gate electrode 8 is separated from gate line 1.

As described above, in the liquid crystal display according to the present embodiment, drain electrode 10 of TFT 7 and gate electrode 8 are separated from pixel electrode 12 and gate line 1, respectively, and therefore, parasitic capacitance Cgd with TFT 7 does not affect the potential of the pixel electrode at the time of normal drive. Accordingly, although the liquid crystal display according to the present embodiment shown in FIG. 8 has a redundant TFT structure having TFTs 3 and TFTs 7, as in the first embodiment, the amount of reduction in the held voltage ΔVgd is small, and a liquid crystal display having high display quality can be obtained. Here, the configuration in FIG. 8 is the same as that shown in FIG. 1, except that the configuration of TFT 7 is different, and therefore, detailed description is omitted.

In addition, the liquid crystal display according to the present embodiment is different from that of the second embodiment in that gate electrode 8 of TFT 7 is cut out from gate line 1, and therefore, the load capacitance of gate line 1 is reduced at the time of normal drive. Therefore, the liquid crystal display according to the present embodiment makes high speed operation possible, as in liquid crystal displays where no spare TFT 7 is formed, and a liquid crystal display having high resolution and no defects can be manufactured with a high yield.

Next, in the liquid crystal display according to the present embodiment, in the case where there is a defect in a normally driven TFT 3, first, the portion between drain electrode 5 of TFT 3 and contact hole 6 is cut using a laser. This cutting is the same as that shown in FIG. 2 according to the first embodiment. Next, a partially formed film portion (not shown) is formed between drain electrode 10 of TFT 7 shown in FIG. 8 and pixel electrode 12, as well as between gate electrode 8 of TFT 7 and gate line 1, through laser CVD, and thus, respective electrical connections are made. As a result of the above described process, in the liquid crystal display according to the present embodiment, normally driven TFT 3 is switched to spare TFT 7, so that the pixel can be driven.

Here also, there is almost no change in the parasitic capacitance between pixel electrode 12 and gate line 1 or source line 2 in the liquid crystal display according to the present embodiment before and after the repairing process. Therefore, it becomes possible for the pixel on which a repairing process has been carried out to gain display properties equal to those of normal pixels when driven under the same drive conditions as normal pixels.

### Fifth Embodiment

FIG. 9 is a plan view showing one pixel of the liquid crystal display according to the present embodiment before a defect is repaired. In FIG. 9, the configuration of TFT 3 is the same as the configuration of TFT 3 shown in FIG. 1, while the configuration of TFT 7 is different from the configuration of TFT 7 shown in FIG. 1. Specifically, TFT 7 shown in FIG. 9 is different from TFT 7 shown in FIG. 1 in that no overlapping portion is provided between drain electrode 10 and pixel electrode 12, and drain electrode 10 is separated from pixel electrode 12. Here, TFT 7 shown in FIG. 9 is different from TFT 7 shown in FIG. 8 in that source electrode 9 is separated from source line 2.

As described above, in the liquid crystal display according to the present embodiment, gate electrode 8 of TFT 7, source electrode 9 and drain electrode 10 are separated from gate line 1, source line 2 and pixel electrode 12, and therefore, parasitic capacitance Cgd with TFT 7 does not affect the potential of the pixel electrode at the time of normal drive. Accordingly, although the liquid crystal display according to the present embodiment shown in FIG. 9 has a redundant TFT structure having TFTs 3 and TFTs 7, as in the first embodiment, the amount of reduction in the held voltage ΔVgd is small, and a liquid crystal display having high display quality can be obtained. Here, in FIG. 9, the same configuration as that shown in FIG. 1 is provided, except that the configuration of TFT 7 is different, and therefore, detailed description is omitted.

In addition, the liquid crystal display according to the present embodiment is different from that of the second embodiment in that gate electrode 8 of TFT 7 is cut out from gate line 1 and source electrode 9 is cut out from source line 2, and therefore, the load capacitance of gate line 1 and source line 2 is reduced at the time of normal drive. Therefore, the liquid crystal display according to the present embodiment makes high speed operation possible, as in liquid crystal displays where no spare TFT 7 is formed, and a liquid crystal display having high resolution and no defects can be manufactured with a high yield.

Next, in the liquid crystal display according to the present embodiment, in the case where there is a defect in a normally driven TFT 3, first, the portion between drain electrode 5 of TFT 3 and contact hole 6 is cut using a laser. This cutting is the same as that shown in FIG. 2 according to the first embodiment. Next, a partially formed film portion (not shown) is formed between drain electrode 10 of TFT 7 shown in FIG. 9 and pixel electrode 12, between gate electrode 8 of TFT 7 and gate line 1, and between source electrode 9 of TFT 7 and source line 2 through laser CVD, and thus, respective electrical connections are made. As a result of the above described process, in the liquid crystal display according to the present embodiment, normally driven TFT 3 is switched to spare TFT 7, so that the pixel can be driven.

Here also, there is almost no change in the parasitic capacitance between pixel electrode 12 and gate line 1 or source line 2 in the liquid crystal display according to the present embodiment before and after the repairing process. Therefore, it becomes possible for the pixel on which a repairing process has been carried out to gain display properties equal to those of normal pixels when driven under the same drive conditions as normal pixels.

While the invention has been shown and described in detail, the foregoing description is in all aspects illustrative and not restrictive. It is therefore understood that numerous modifications and variations can be devised without departing from the scope of the invention.

What is claimed is:

1. A liquid crystal display, comprising:
a plurality of gate lines;
a plurality of source lines provided to be perpendicular to said gate lines;
a plurality of pixel electrodes provided in a matrix form corresponding to intersections of said gate lines and said source lines;
a first TFT having a first gate electrode connected to one of said gate lines, a first source electrode connected to one of said source lines, and a first drain electrode connected to one of said pixel electrodes, provided for each of said pixel electrodes; and
a second TFT having a second gate electrode, a second source electrode and a second drain electrode, provided for each of said pixel electrodes,
wherein said second TFT either does not have a portion which overlaps with any of said gate lines in a plane, and/or does not have a portion which overlaps with any of said pixel electrodes in a plane, and said second gate electrodes and said gate lines and/or said second drain electrodes and said pixel electrodes are not electrically connected.

2. The liquid crystal display according to claim 1, wherein
the second TFT does not have a portion which overlaps with any of said gate lines in a plane, and said second gate electrodes and said gate lines, as well as said second source electrodes and said source lines, are not electrically connected.

3. The liquid crystal display according to claim 1, wherein
the second TFT does not have a portion which overlaps with any of said pixel electrodes in a plane, and said second drain electrodes and said pixel electrodes are not electrically connected.

4. The liquid crystal display according to claim 1, wherein
the second TFT does not have a portion which overlaps with any of said pixel electrode in a plane, and said second source electrodes and said source lines, as well as said second drain electrodes and said pixel electrodes, are not electrically connected.

5. The liquid crystal display according to claim 1, wherein
the second TFT does not have a portion which overlaps with any of said gate lines and said pixel electrodes in a plane, and said second gate electrodes and said gate lines, as well as said second drain electrodes and said pixel electrodes, are not electrically connected.

6. The liquid crystal display according to claim 1, wherein
the second TFT does not have a portion which overlaps with any of said gate lines and said pixel electrodes in a plane, and said second gate electrodes and said gate lines, said second source electrodes and said source lines, and said second drain electrodes and said pixel electrodes are not electrically connected.

7. A defect repairing method for a liquid crystal display which comprises:
a plurality of gate lines;
a plurality of source lines provided to be perpendicular to said gate lines;
a plurality of pixel electrodes provided in a matrix form corresponding to intersections of said gate lines and said source lines;
a first TFT having a first gate electrode connected to one of said gate lines, a first source electrode connected to one of said source lines, and a first drain electrode connected to one of said pixel electrodes, provided for each of said pixel electrodes; and
a second TFT having a second gate electrode, a second source electrode and a second drain electrode, provided for each of said pixel electrodes, wherein
said second TFT either does not have a portion which overlaps with any of said gate lines in a plane, and/or does not have a portion which overlaps with any of said pixel electrodes in a plane, and said second gate electrodes and said gate lines and/or said second drain electrodes and said pixel electrodes are not electrically connected,
the method comprising the steps of
cutting out a first drain electrode of a first TFT having a defect from a pixel electrode; and
making a connection in an electrically unconnected portion from among the portion between the second gate electrode of the second TFT corresponding to those in said first TFT having a defect and the gate line, the portion between the second source electrode and the source line, and the portion between the second drain electrode and the pixel electrode, in accordance with a predetermined film forming technique.

8. The defect repairing method for a liquid crystal display according to claim 7, wherein
said film forming technique is a laser CVD method.
